(19) United States
(12) Patent Application Publication
(10) Pub. No.: US 2022/0140799 A1
(43) Pub. Date: May 5, 2022

(54) DEVICE FOR SUPPRESSING EMC COMMON-MODE INTERFERENCE IN MOTOR VEHICLE HIGH-VOLTAGE APPILCATIONS

(71) Applicant: Webasto SE, Stockdorf (DE)

(72) Inventor: HANS RECHBERGER, Stockdorf (DE)

(21) Appl. No.: 17/430,034

(22) PCT Filed: Feb. 13, 2020
(86) PCT No.: PCT/EP2020/053727

§ 371 Date: Aug. 11, 2021

(30) Foreign Application Priority Data
Feb. 15, 2019 (DE) 10 2019 103 832.4

(51) Int. Cl. H03H 7/01; B60R 16/02

(52) U.S. Cl. CPC H03H 7/0138; B60R 16/02

(57) ABSTRACT

A device for suppressing EMC common-mode interference in motor vehicle high-voltage applications, having Y-capacitors in a V-configuration between positive and negative high voltage (HV+, HV−) and chassis ground. Y-capacitors can be connected in a V-configuration to be connected to the chassis ground via series-connected Y-capacitors.

This application represents the national stage entry of PCT International Application No. PCT/EP2020/053727 filed on Feb. 13, 2020, which claims the benefit of German Patent Application No. 10 2019 103 832.4 filed on Feb. 15, 2019, the entire contents of which are incorporated herein by reference for all purposes.

The disclosure relates to a device for suppressing EMC common-mode interference in motor vehicle high-voltage applications, having Y capacitors in a V configuration between the positive and negative high voltages and the chassis ground.

In order to block and damp interference signals used in motor vehicle high-voltage components, for example, radio interference suppression capacitors that are defined in classes X and Y depending on the requirements profile are used.

According to IEC 60384-1, class X capacitors are electrical capacitors with “unlimited capacitance” that are connected between the phase and neutral conductors or between two phases. They are prescribed for applications in which the failure thereof due to a short circuit cannot result in a dangerous electric shock.

Class X radio interference suppression capacitors are divided into subclasses as follows:

| | Pulse peak voltage | Required |
|---|---|---|
| Application | during operation | pulse capacity |
| Use at high peak voltages | 2.5 kV-4 kV | 4 kV for C ≤ 1 μF |
| General requirements | ≤2.5 kV | 2.5 kV for C ≤ 1 μF |
| General requirements | ≤1.2 kV | — |

Class Y capacitors according to IEC 60384-1 are capacitors that are connected between a phase or neutral conductor and a touchable, protectively grounded apparatus housing and therefore bridge the basic insulation. According to this standard, permissible Y capacitors are those capacitors that have verifiable increased electrical and mechanical safety with limited capacitance, since if they are used in the case of a failure due to a short circuit, there can be a danger to people or animals as a result of electric shock.

Class Y radio interference suppression capacitors are divided into subclasses as follows:

| | | Rated voltage | |
|---|---|---|---|
| | | range | Required |
| | Type of bridged | (nominal voltage | pulse |
| Subclass | insulation | range) | capacity |
| Y1 | Double or | ≤500 VAC | 8 kV |
| | reinforced | | |
| | insulation | | |
| Y2 | Basic or additional | ≥150 VAC-≤300 VAC | 5 kV |
| | insulation | | |
| Y3 | Basic or additional | ≥150 VAC-≤250 VAC | — |
| | insulation | | |
| Y4 | Basic or additional | <150 VAC | 2.5 kV |
| | insulation | | |

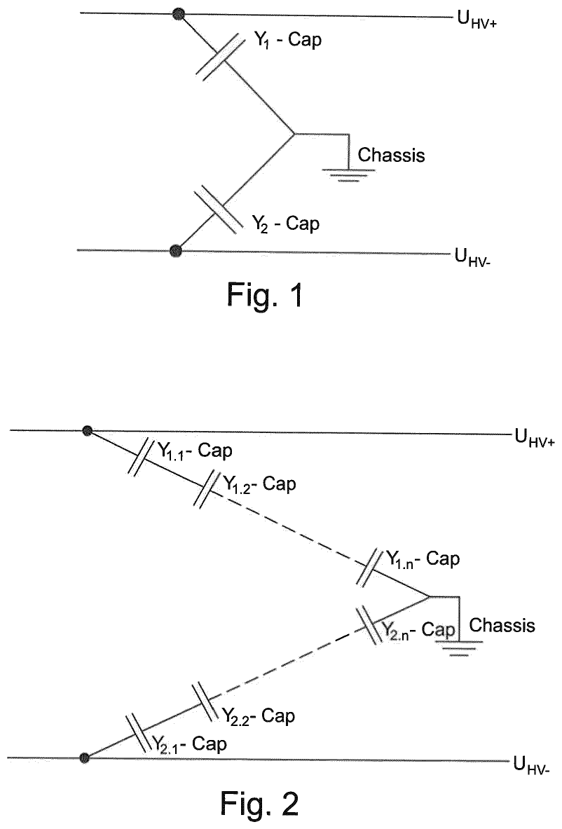

Known circuit measures for suppressing EMC common-mode interference in high-voltage applications by means of radio interference suppression capacitors are shown in FIGS. 1 and 2 and are explained below.

In high-voltage components whose electrical loads, for example the heating core of a heater, have a capacitive cover opposite the chassis, capacitive currents are conducted to the chassis when these loads are switched. These currents can cause interference in other electrical components in the electrical system; this is referred to as EMC common-mode interference.

A measure for suppressing this EMC common-mode interference is Y2 capacitors connected between HV+ and the chassis and HV− and the chassis in a V configuration, as shown in FIG. 1, by way of which capacitors the interference currents are conducted from the chassis back into the HV system. The capacitors used in the circuit in FIG. 1 are rated Y2 capacitors according to IEC 60384-1 that are used in industry and are tested and approved according to the standard LV123 (“Electrical characteristics and electrical safety of high-voltage components in motor vehicles”).

For motor vehicle high-voltage applications, however, Y2 capacitors are not suitable, for the following reasons:
The nominal voltage of these capacitors is 230 V_{AC} or 400 V_{AC}; in contrast, capacitors with a nominal voltage of 530 V_{DC} or 930 V_{DC} are needed in motor vehicle applications.
The temperature range of these capacitors (film capacitors) is −10° C. . . . 85° C.; in contrast, capacitors with a temperature range of −40° C. . . . 125° C. are needed in motor vehicle applications.

If Y2-rated capacitors cannot be used, at least 2 capacitors have to be connected in series according to the LV123 standard, for example, as shown in FIG. 2. When ceramic capacitors are used, this additionally means that, depending on the component size, more than 2 capacitors in series may even be necessary to meet the creepage distance requirements according to the LV123 standard.

A device for suppressing EMC common-mode interference in motor vehicle high-voltage applications is disclosed, for example, in CN101997403A. In this device an X capacitor is connected upstream of the Y capacitors connected in a V configuration between the positive and negative high voltages and the chassis ground.

It is an object of the disclosure to provide a device of the type mentioned at the outset that guarantees greater suppression of EMC common-mode interference in motor vehicle high-voltage applications than previous devices for this purpose and that can be produced in a cost-effective manner.

This object is achieved by the features of claim 1. Advantageous developments of the disclosure are defined in the dependent claims.

The disclosure accordingly provides a device for suppressing EMC common-mode interference in motor vehicle high-voltage applications, having Y capacitors in a V configuration between the positive and negative high voltages and the chassis ground, wherein the Y capacitors connected in a V configuration are connected to the chassis ground via Y capacitors connected in series.

The Y capacitors are advantageously connected according to the disclosure in such a way that a series circuit according to standard LV123 is created and the required creepage distances are achieved. This series circuit can be formed with a smaller number of capacitors than in the case of the prior art according to FIG. 2.

The circuit of the device according to the disclosure can be produced with lower costs than in the prior art because low-voltage capacitors can be used as Y capacitors, in contrast to the Y2-rated high-voltage capacitors that are required in the prior art.

Advantageously, an X capacitor is formed by the series circuit of the Y capacitors, which X capacitor contributes to optimizing the suppression of EMC common-mode interference achievable with the device according to the disclosure without additional component complexity in order to provide the function of an X capacitor. In particular, the X capacitor provides suppression of high-frequency common-mode interference.

Advantageously, the device according to the disclosure is used for effective interference suppression for the heating core of a heater that has a capacitive cover opposite the chassis.

The disclosure is explained in greater detail below with reference to the drawing, in which:

FIG. 1 shows a device for suppressing EMC common-mode interference with Y2 capacitors connected in a V configuration between HV+ and the chassis and HV− and the chassis according to the prior art,

FIG. 2 shows a device for suppressing EMC common-mode interference with Y capacitors, which are not Y2-rated, connected in a V configuration between HV+ and the chassis and HV− and the chassis according to the prior art, and

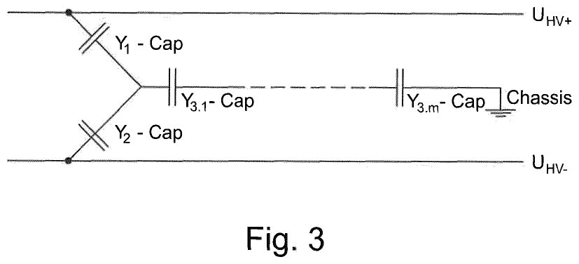

FIG. 3 shows an embodiment of the device according to the disclosure for suppressing EMC common-mode interference with Y capacitors, which are not Y2-rated, connected in a V configuration between HV+ and the chassis and HV− and the chassis.

FIGS. 1 and 2 are explained in the introduction in relation to the prior art.

An embodiment of the device according to the disclosure is shown in FIG. 3.

This embodiment differs from the device shown in FIG. 2 in that the Y capacitors, which are not Y2-rated, connected in a V configuration are connected to the chassis ground via Y capacitors connected in series.

The series circuit is configured in such a way that a series circuit according to standard LV123 is obtained and the required creepage distances are achieved. This series circuit can be formed with a smaller number of capacitors than in the case of the prior art according to FIG. 2.

The circuit of the device according to the disclosure can be implemented with lower costs than in the prior art because low-voltage capacitors can be used as Y capacitors, in contrast to the Y2-rated high-voltage capacitors that are required in the prior art.

Furthermore, an X capacitor is formed by the series circuit of the Y capacitors, which X capacitor contributes to optimizing the suppression of EMC common-mode interference achievable with the device according to the disclosure without additional component complexity in order to provide the function of an X capacitor. The X capacitor provides suppression of high-frequency common-mode interference.

1. A device for suppressing EMC common-mode interference in motor vehicle high-voltage applications, having Y capacitors in a V configuration between the positive and negative high voltages (HV+, HV−) and the chassis ground, wherein the Y capacitors connected in a V configuration are connected to the chassis ground via Y capacitors connected in series.

2. The device as claimed in claim 1, wherein the Y capacitors are connected in series in accordance with the standard LV123 to achieve creepage distances according to the standard LV123.

3. The device as claimed in claim 1, wherein an X capacitor is formed by the series circuit of the Y capacitors.

4. A heating core of a heater comprising the device for suppressing EMC common-mode interference of claim 1 and a capacitive cover opposite the chassis.

5. The heating core of claim 4, wherein the device for suppressing EMC common-mode interference comprises Y capacitors are connected in series in accordance with the standard LV123 to achieve creepage distances according to the standard LV123

6. The heating core of claim 4, wherein the device for suppressing EMC common-mode interference comprises an X capacitor is formed by the series circuit of the Y capacitors.

7. The heating core of claim 4, wherein the device for suppressing EMC common-mode interference comprises Y capacitors are connected in series in accordance with the standard LV123 to achieve creepage distances according to the standard LV123 and wherein an X capacitor is formed by the series circuit of the Y capacitors.

8. The device as claimed in claim 1, wherein the Y capacitors are connected in series in accordance with the standard LV123 to achieve creepage distances according to the standard LV123 and wherein an X capacitor is formed by the series circuit of the Y capacitors.
